(19) United States
(12) Patent Application Publication
(10) Pub. No.: US 2025/0336799 A1
(43) Pub. Date: Oct. 30, 2025

(54) SEMICONDUCTOR PACKAGE

(71) Applicant: Samsung Electronics Co., Ltd., Suwon-si (KR)

(72) Inventor: Junghoon Kang, Suwon-si (KR)

(21) Appl. No.: 19/016,457

(22) Filed: Jan. 10, 2025

(30) Foreign Application Priority Data
Apr. 24, 2024 (KR) 10-2024-0054988

(51) Int. Cl. H01L 23/498; H01L 21/48; H01L 23/00; H01L 23/13; H01L 23/15; H01L 23/538; H01L 25/065; H01L 25/18; H10B 80/00; H10D 80/30

(52) U.S. Cl. CPC H01L 23/49894; H01L 21/4857; H01L 21/486; H01L 23/13; H01L 23/15; H01L 23/49822; H01L 23/49838; H01L 23/5383; H01L 23/5386; H01L 25/0655; H01L 25/18; H01L 24/16; H01L 24/32; H01L 24/73; H01L 2224/16227; H01L 2224/16238; H01L 2224/32225; H01L 2224/73204; H01L 2924/35121; H10B 80/00; H10D 80/30

(57) ABSTRACT

Provided is a semiconductor package including a glass core interposer including a glass core substrate, a plurality of through electrodes penetrating the glass core substrate, a first insulating layer at least partially covering each of an upper surface and a lower surface of the glass core substrate, a second insulating layer at least partially surrounding the first insulating layer and the glass core substrate, and an upper redistribution layer on an upper surface of the second insulating layer, and a first semiconductor device on an upper surface of the glass core interposer, wherein the first insulating layer is free of filler, and the second insulating layer includes filler.

### CROSS-REFERENCE TO RELATED APPLICATION

This application is based on and claims priority under 35 U.S.C. § 119 to Korean Patent Application No. 10-2024-0054988, filed on Apr. 24, 2024, in the Korean Intellectual Property Office, the disclosure of which is incorporated by reference herein in its entirety.

### FIELD

The inventive concept relates to a semiconductor package, and more particularly, to a semiconductor package including a glass core interposer.

### BACKGROUND

With the development of the electronics industry, demand for high functionality, high speed, and miniaturization of electronic components has increased. According to this trend, there may be an increasing need for miniaturization and multi-functionalization of semiconductor chips used in electronic components. In addition, improving the reliability of semiconductor packages may be important. In semiconductor packages, organic interposers, silicon interposers, etc. are used as interposers, and the use of glass interposers including glass cores is also being researched.

### SUMMARY

The inventive concepts may improve the reliability of a semiconductor package including a glass core substrate.

The inventive concepts are not limited to the foregoing, and other unmentioned advantages would be clearly understood by those skill in the art from the following description.

According to an aspect of the inventive concept, there is provided a semiconductor package including a glass core interposer including a glass core substrate, a plurality of through electrodes penetrating the glass core substrate, a first insulating layer at least partially covering each of an upper surface and a lower surface of the glass core substrate that is opposite the upper surface thereof, a second insulating layer at least partially surrounding the first insulating layer and the glass core substrate, and an upper redistribution layer on an upper surface of the second insulating layer, and a first semiconductor device on an upper surface of the glass core interposer, wherein the first insulating layer does not include or is free of filler, and the second insulating layer includes filler.

According to another aspect of the inventive concept, there is provided a semiconductor package including a glass core interposer including a glass core substrate, a plurality of through electrodes penetrating the glass core substrate, a first insulating layer at least partially covering each of an upper surface and a lower surface of the glass core substrate that is opposite the upper surface thereof, a second insulating layer at least partially surrounding the first insulating layer and the glass core substrate, an upper redistribution layer on an upper surface of the second insulating layer, upper core vias connected to upper ends of the plurality of through electrodes, and lower core vias connected to lower ends of the plurality of through electrodes, and a first semiconductor device on an upper surface of the glass core interposer, wherein the first insulating layer includes a first upper-surface insulating layer at least partially covering the upper surface of the glass core substrate, and a first lower-surface insulating layer at least partially covering the lower surface of the glass core substrate, at least one of the upper core vias at least partially penetrate the first upper-surface insulating layer, at least one of the lower core vias at least partially penetrate the first lower-surface insulating layer, and at least one of the upper core vias and at least one of the lower core vias are not in contact with the second insulating layer.

According to another aspect of the inventive concept, there is provided a semiconductor package including a glass core interposer including a glass core substrate, a plurality of through electrodes penetrating the glass core substrate, a first insulating layer at least partially covering each of an upper surface and a lower surface of the glass core substrate that is opposite the upper surface thereof, a second insulating layer at least partially surrounding the first insulating layer and the glass core substrate, an upper redistribution layer on an upper surface of the second insulating layer, and a lower redistribution layer on a lower surface of the second insulating layer that is opposite the upper surface thereof, a first semiconductor device on an upper surface of the glass core interposer, upper core vias connected to upper ends of the plurality of through electrodes, and lower core vias connected to lower ends of the plurality of through electrodes, wherein the first insulating layer includes a first upper-surface insulating layer at least partially covering the upper surface of the glass core substrate, and a first lower-surface insulating layer at least partially covering the lower surface of the glass core substrate, the second insulating layer includes a second upper-surface insulating layer at least partially covering the first upper-surface insulating layer, and a second lower-surface insulating layer at least partially covering the first lower-surface insulating layer, an outer edge of the first upper-surface insulating layer and an outer edge of the first lower-surface insulating layer are coplanar with an outer edge of the glass core substrate, the second insulating layer at least partially surrounds a side surface of the glass core substrate and at least partially surrounds side surfaces of the first upper-surface insulating layer and the first lower-surface insulating layer, a side surface of the second insulating layer is laterally spaced apart from or laterally extends beyond the side surface of the glass core substrate, a planar area of the second insulating layer is larger than planar areas of the first upper-surface insulating layer and the first lower-surface insulating layer, the first insulating layer does not include or is free of filler, the second insulating layer includes filler, the upper core vias at least partially penetrate the first upper-surface insulating layer and the second upper-surface insulating layer, the lower core vias at least partially penetrate the second upper-surface insulating layer and the second lower-surface insulating layer, respective levels of one surface of the first upper-surface insulating layer, one end of the through electrode, and one surface of the upper core vias are identical to each other in a direction away from the glass core substrate, respective levels of one surface of the first lower-surface insulating layer, one end of the through electrode, and one surface of the lower core vias are identical to each other in a direction away from the glass core substrate, the upper redistribution layer includes an upper redistribution pattern and an upper redistribution insulating layer, the upper redistribution pattern includes an upper redistribution line pattern and an upper redistribution via pattern, the upper redistribution via pattern has a horizontal width that increases with distance away from the glass core substrate, the lower redistribution layer includes a lower redistribution pattern and a lower redistribution insulating layer, the lower redistribution pattern includes a lower redistribution line pattern and a lower redistribution via pattern, and the lower redistribution via pattern has a horizontal width that increases with distance away from the glass core substrate.

### BRIEF DESCRIPTION OF THE DRAWINGS

Embodiments will be more clearly understood from the following detailed description taken in conjunction with the accompanying drawings in which:

FIG. 1 is a cross-sectional view illustrating a semiconductor package according to embodiments;

FIG. 2 is a cross-sectional view illustrating a semiconductor package according to embodiments;

FIG. 3 is a cross-sectional view illustrating a semiconductor package according to embodiments;

FIG. 4 is a cross-sectional view illustrating a semiconductor package according to embodiments;

FIGS. 5A, 5B, 5C, 5D, 5E, 5F, 5G, 5H, 5I, and 5J are cross-sectional views illustrating a process of manufacturing a semiconductor package, according to embodiments; and

FIGS. 6A, 6B, 6C, 6D, 6E, 6F, 6G, 6H, 6I, 6J, and 6K are cross-sectional views illustrating a process of manufacturing a semiconductor package, according to embodiments.

### DETAILED DESCRIPTION OF THE EMBODIMENTS

Hereinafter, embodiments of the inventive concept will be described in detail with reference to the accompanying drawings.

Embodiments of the inventive concept are provided to more completely explain the inventive concept to those of skill in the art, and the following embodiments may be variously modified, and the scope of the inventive concept is not limited to the following embodiments. Rather, the embodiments are provided such that the inventive concept is thorough and complete, and will fully convey the inventive concept to those skill in the art. In addition, the thickness or size of each layer in the drawings is exaggerated for convenience and clarity of description.

In the present specification, a first direction refers to an X direction, a second direction refers to a Y direction, and the first direction and the second direction may be perpendicular to each other. A third direction refers to a Z direction, and the third direction may be perpendicular to each of the first direction and the second direction. A horizontal plane or a plane refers to an X-Y plane. An upper surface of a particular object refers to a surface located in the positive third direction with respect to the object, and a lower surface of a particular object refers to a surface located in the negative third direction with respect to the object. It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

The term “surrounding” or “covering” or “penetrating” as may be used herein may not require completely surrounding or covering or penetrating the described elements or layers, but may, for example, refer to partially surrounding or covering or penetrating the described elements or layers, for example, with voids or other discontinuities throughout.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. When a first component or layer are referred to herein as “on” a second component or layer, it will be understood that the first component or layer exists in a positive axial direction with respect to the second component or layer, with intervening components or layers potentially in between. Conversely, when components are “directly on” or “immediately” adjacent to one another, no intervening components may be present.

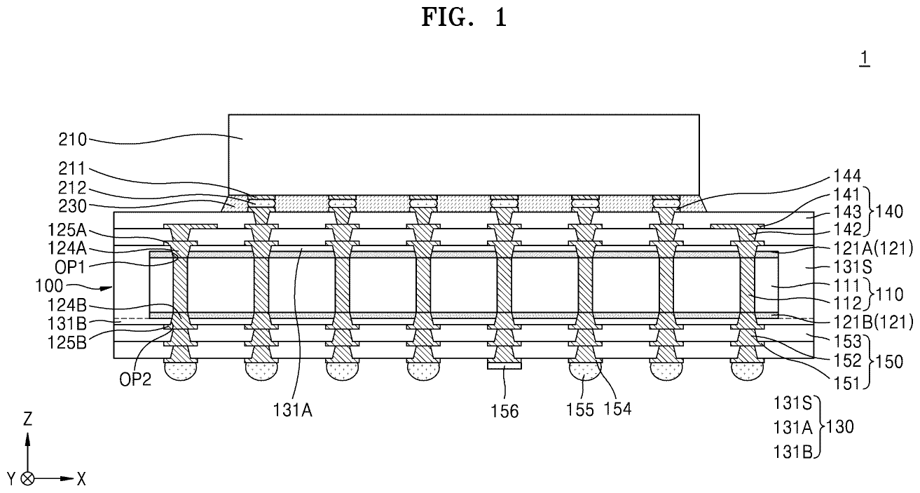

FIG. 1 is a cross-sectional view illustrating a semiconductor package 1 according to embodiments.

Referring to FIG. 1, the semiconductor package 1 according to embodiments may include a glass core interposer 100 and a first semiconductor device 210 arranged on the glass core interposer 100. The glass core interposer 100 may include a glass core substrate 110, a first insulating layer 121, a second insulating layer 130, and an upper redistribution layer 140. The glass core substrate 110 may include a glass body 111 and through electrodes 112.

The glass body 111 may include glass. In general, glass has excellent properties such as smoothness, a significantly low coefficient of thermal expansion of about 9.0*10−6/° C., and a high hardness of about 6 H to about 7 H. In the semiconductor package 1 of the present embodiment, the glass used in the glass body 111 of the glass core substrate 110 may be reinforced glass with high tensile strength and high rigidity.

The glass body 111 may have the shape of a quadrangular flat plate. The glass body 111 may have a thickness of about 50 μm to about 1500 μm. However, the thickness of the glass body 111 is not limited to the above numerical range. In addition, in the glass body 111 in the flat plate shape, an upper surface or a lower surface may correspond to an X-Y plane, and a thickness direction may correspond to a Z direction.

The through electrode 112 may have a structure that extends in the Z direction to penetrate the glass body 111. Accordingly, an upper end and a lower end of the through electrode 112 may be exposed from the upper surface and the lower surface of the glass body 111, respectively. The through electrode 112 may have, for example, a cylindrical shape penetrating the glass body 111. However, the shape of the through electrode 112 is not limited to the cylindrical shape. For example, according to an embodiment, the through electrode 112 may have the shape of an elliptical column or a polygonal column. For reference, the through electrode 112 has a structure that penetrates glass, and thus may be referred to as a through glass via (TGV).

As used herein, the term “exposed” may be used to describe relationships between elements and/or certain intermediate processes in fabricating a completed semiconductor device, but may not necessarily require exposure of the particular region, layer, structure or other element in the context of the completed device.

In addition, the through electrodes 112 may be arranged in a two-dimensional array structure inside the glass body 111. In the semiconductor package 1 of the present embodiment, the signal integrity (SI) performance may be improved by minimizing the pitch of the through electrode 112 in the glass core substrate 110.

The through electrode 112 may include a metal, a conductive metal oxide, a conductive metal nitride, etc. For example, the through electrode 112 may include copper (Cu), tungsten (W), aluminum (Al), nickel (Ni), cobalt (Co), titanium (Ti), titanium nitride (TiN), etc. In detail, in the semiconductor package 1 of the present embodiment, the through electrode 112 of the glass core substrate 110 may include Cu. The through electrode 112 may be formed, for example, through electroplating. However, the inventive concept is not limited thereto, and the through electrode 112 may also be formed through other processes such as deposition or sputtering.

The width of the through electrode 112 may be about 3 μm to about 100 μm. Here, the width of the through electrode 112 may be defined differently depending on the shape of the through electrode 112. For example, in a case in which the through electrode 112 has a cylindrical shape, the width of the through electrode 112 may correspond to the diameter of a circle.

In addition, the side surface of the through electrode 112 may be surrounded by an adhesive layer. The adhesive layer may be a film that adheres the through electrode 112 and the glass body 111 to each other. The adhesive layer may include a conductive material or a non-conductive material. For example, the adhesive layer may include Ni, tin (Sn), Ti, titanium tungsten (TiW), silicon nitride (SiN), etc. However, the material of the adhesive layer is not limited to the materials described above. The adhesive layer may have a thickness of 1 μm or less, but the thickness of the adhesive layer is not limited to 1 μm or less.

The first insulating layer 121 may include a first upper-surface insulating layer 121A and a first lower-surface insulating layer 121B. The first insulating layer 121 may cover the upper surface and the lower surface of the glass core substrate 110. In other words, the first upper-surface insulating layer 121A may cover the upper surface of the glass core substrate 110, and the first lower-surface insulating layer 121B may cover the lower surface of the glass core substrate 110.

The outer edge of the glass core substrate 110, the outer edge of the first upper-surface insulating layer 121A, and the outer edge of the first lower-surface insulating layer 121B may coincide with each other. That is, the planar area of the glass core substrate 110, the planar area of the first upper-surface insulating layer 121A, and the planar area of the first lower-surface insulating layer 121B may be identical to each other. In other words, the side surface of the first upper-surface insulating layer 121A and the side surface of the first lower-surface insulating layer 121B may be aligned vertically with the side surface of the glass core substrate 110.

As used herein, a portion of a component or layer that “coincides” with another portion of a component or layer is substantially flush, or coplanar, with that portion of the component or layer.

The second insulating layer 130 may surround the glass core substrate 110 and the first insulating layer 121. The second insulating layer 130 may cover the upper surface of the first upper-surface insulating layer 121A and the lower surface of the first lower-surface insulating layer 121B, both included in the first insulating layer 121. In addition, the second insulating layer 130 may simultaneously cover the side surface of the first upper-surface insulating layer 121A, the side surface of the first lower-surface insulating layer 121B, and the side surface of the glass core substrate 110.

The second insulating layer 130 may include a second side-surface insulating layer 131S, a second upper-surface insulating layer 131A, and a second lower-surface insulating layer 131B. The second upper-surface insulating layer 131A may cover the upper surface of the first upper-surface insulating layer 121A, and the second lower-surface insulating layer 131B may cover the lower surface of the first lower-surface insulating layer 121B. The second side-surface insulating layer 131S may simultaneously cover the side surface of the first upper-surface insulating layer 121A, the side surface of the first lower-surface insulating layer 121B, and the side surface of the glass core substrate 110. For example, the second insulating layer 130 may cover the side surface of the first upper-surface insulating layer 121A, the side surface of the first lower-surface insulating layer 121B, and the side surface of the glass core substrate 110.

The side surface of the second insulating layer 130 may be spaced apart from the side surface of the glass core substrate 110. That is, the planar area of the second insulating layer 130 may be larger than the planar area of the first insulating layer 121 and the planar area of the glass core substrate 110. The side surface of the second insulating layer 130 may be spaced laterally from or may laterally extend beyond the side surface of the glass core substrate 110 by 30 μm to 500 μm. That is, the horizontal width of the second side-surface insulating layer 131S may be 30 μm to 500 μm.

In another embodiment, the side surface of the second side-surface insulating layer 131S, the glass core substrate 110, and the side surface of the first insulating layer 121 may be vertically aligned with each other. That is, the planar area of the glass core substrate 110, the planar area of the first insulating layer 121, and the planar area of the second insulating layer 130 may be identical to each other.

The second side-surface insulating layer 131S, the second upper-surface insulating layer 131A, and the second lower-surface insulating layer 131B may have the same material composition. The second side-surface insulating layer 131S and the second upper-surface insulating layer 131A may be formed integrally with each other, and the second lower-surface insulating layer 131B may be formed separately from the second side-surface insulating layer 131S and the second upper-surface insulating layer 131A. Alternatively, the second lower-surface insulating layer 131B may be simultaneously formed integrally with the second side-surface insulating layer 131S and the second upper-surface insulating layer 131A.

The first insulating layer 121 may include a polymer, a dielectric film, etc. The first insulating layer 121 may be made of a photoimageable dielectric or a non-photoimageable dielectric. In a case in which the first insulating layer 121 is made of a photoimageable dielectric, for example, the first insulating layer 121 may include a photosensitive polymer. The photosensitive polymer may be formed of at least one of, for example, a photosensitive polyimide, polybenzoxazole, a phenol-based polymer, and a benzocyclobutene-based polymer. Alternatively, the first insulating layer 121 may include lead oxide (PbO), polyhydroxystyrene (PHS), or the like including a photosensitizer. In a case in which the first insulating layer 121 is made of a non-photoimageable dielectric, for example, the first insulating layer 121 may be formed of a silicon oxide film, a silicon nitride film, or a silicon oxynitride film. The first insulating layer 121 may be formed by a vapor deposition process, a spin coating process, or the like. However, the first insulating layer 121 may not include a filler.

The second insulating layer 130 may be made of an insulating material including a filler. For example, the second insulating layer 130 may be a thermosetting resin such as an epoxy resin, a thermoplastic resin such as a polyimide, or such a resin with an inorganic filler or/and glass fiber (glass cloth or glass fabric) mixed as a filler. For example, Ajinomoto Build-up Film (ABF) and prepreg may be used for the second insulating layer 130.

In a case in which, without the first insulating layer 121, for example, ABF is used as a material of the second insulating layer 130, the second insulating layer 130 may be directly attached to the glass core substrate 110 through a lamination process. In this case, the second insulating layer 130 including a filler may have reduced adhesion at an interface with the glass core substrate 110. Due to the pressure in the lamination process, the filler (e.g., SiO₂) included in the second insulating layer 130 may be excessively distributed at the interface with the glass core substrate 110. That is, the adhesion between the second insulating layer 130 and the glass core substrate 110 may be reduced due to the excessive distribution of the filler. Accordingly, the second insulating layer 130 and the glass core substrate 110 may be partially peeled off. This may lead to a reliability issue in the semiconductor package.

Unlike the above-described case in which ABF is used as a material of the second insulating layer 130 without the first insulating layer 121, and the second insulating layer 130 is directly attached to the glass core substrate 110, in the semiconductor package 1 according to embodiments, the first insulating layer 121 that does not include a filler is arranged between the second insulating layer 130 and the glass core substrate 110. Because the first insulating layer 121 does not include a filler, the adhesion between the first insulating layer 121 and the glass core substrate 110 may be improved or secured. In addition, even in a case in which the second insulating layer 130 includes a filler, the adhesion between the second insulating layer 130 and the first insulating layer 121 may be improved or sufficiently secured as compared to the adhesion between the second insulating layer 130 and the glass core substrate 110, and thus, the reliability of the semiconductor package 1 according to embodiments may be improved.

In addition, in the semiconductor package 1 according to embodiments, the second insulating layer 130 laterally extends beyond and/or surrounds the side surface of the glass core substrate 110, and thus, the second insulating layer 130 may protect the glass core substrate 110, and the possibility of the first insulating layer 121 and the glass core substrate 110 being peeled off or delaminated may be further reduced. Thus, the reliability of the semiconductor package 1 according to embodiments may be improved.

A first opening OP1 may simultaneously penetrate the first upper-surface insulating layer 121A and the second upper-surface insulating layer 131A. An upper core via 124A may be provided inside the first opening OP1. The upper core via 124A may simultaneously penetrate the first upper-surface insulating layer 121A and the second upper-surface insulating layer 131A. The upper core via 124A may be in contact with the upper end of the through electrode 112. The upper end of the through electrode 112 may have the same vertical level as the upper surface of the glass core substrate 110. The vertical height of the upper core via 124A may be substantially equal to the sum of the vertical thicknesses of the first upper-surface insulating layer 121A and the second upper-surface insulating layer 131A. A part of the side surface of the upper core via 124A may be in contact with the first upper-surface insulating layer 121A, and the other part of the side surface of the upper core via 124A may be in contact with the second upper-surface insulating layer 131A.

A second opening OP2 may simultaneously penetrate the first lower-surface insulating layer 121B and the second lower-surface insulating layer 131B. A lower core via 124B may be provided inside the second opening OP2. The lower core via 124B may simultaneously penetrate the first lower-surface insulating layer 121B and the second lower-surface insulating layer 131B. The lower core via 124B may be in contact with the lower end of the through electrode 112. The lower end of the through electrode 112 may have the same vertical level as the lower surface of the glass core substrate 110. The vertical height of the lower core via 124B may be substantially equal to the sum of the vertical thicknesses of the first lower-surface insulating layer 121B and the second lower-surface insulating layer 131B. A part of the side surface of the lower core via 124B may be in contact with the first lower-surface insulating layer 121B, and the other part of the side surface of the lower core via 124B may be in contact with the second lower-surface insulating layer 131B.

An upper core pad 125A may be provided at one end of the upper core via 124A. The upper core pad 125A and the upper core via 124A may be formed as one body. The upper core pad 125A may be provided on the upper surface of the second insulating layer 130. That is, the upper core pad 125A may be arranged on the second upper-surface insulating layer 131A. Similarly, the lower core via 124B may be provided at one end of a lower core pad 125B. The lower core pad 125B and the lower core via 124B may be formed as one body. The lower core pad 125B may be provided on the lower surface of the second insulating layer 130. That is, the lower core pad 125B may be arranged on the second lower-surface insulating layer 131B.

The upper redistribution layer 140 may be provided on the second upper-surface insulating layer 131A. The upper redistribution layer 140 may include upper redistribution insulating layers 143, a plurality of upper redistribution line patterns 141 arranged on at least some of the upper surfaces or lower surfaces of the upper redistribution insulating layers 143, and a plurality of upper redistribution via patterns 142 penetrating the upper redistribution insulating layers 143 and in contact with some of the plurality of upper redistribution line patterns 141. The upper redistribution via pattern 142 may have a tapered shape of which the horizontal width increases away from the glass core substrate 110. The plurality of upper redistribution line patterns 141 and the plurality of upper redistribution via patterns 142 may be collectively referred to as upper redistribution patterns.

Each of the upper redistribution insulating layers 143 may be formed from a material film including, for example, an organic compound. In some embodiments, each of the upper redistribution insulating layers 143 may be formed from a material film including an organic polymer material. In some embodiments, each of the upper redistribution insulating layers 143 may be formed from a photosensitive polyimide (PSPI).

Each of the plurality of upper redistribution line patterns 141 and the plurality of upper redistribution via patterns 142 may be a metal, such as copper (Cu), tungsten (W), titanium (Ti), titanium tungsten (TiW), titanium nitride (TiN), tantalum (Ta), tantalum nitride (TaN), chromium (Cr), aluminum (Al), indium (In), molybdenum (Mo), manganese (Mn), cobalt (Co), tin (Sn), nickel (Ni), magnesium (Mg), rhenium (Re), beryllium (Be), gallium (Ga), or ruthenium (Ru), an alloy thereof, or a metal nitride, but is not limited thereto.

Each of the plurality of upper redistribution line patterns 141 and the plurality of upper redistribution via patterns 142 may be formed of a seed layer in contact with the upper redistribution insulating layer 143, and a conductive material layer on the seed layer. In some embodiments, the seed layer may be formed by performing physical vapor deposition, and the conductive material layer may be formed by performing electroless plating. The upper core via 124A and the upper core pad 125A may also be formed of a seed layer and a conductive material layer on the seed layer, as described above.

Some of the plurality of upper redistribution line patterns 141 may be formed together with some of the upper redistribution via patterns 142 to form one body. For example, the plurality of upper redistribution line patterns 141 may be formed together with portions of the upper redistribution via patterns 142 that are in contact with the upper side of the plurality of upper redistribution line patterns 141 or portions of the upper redistribution via patterns 142 that are in contact with the lower side of the plurality of upper redistribution line patterns 141, to form one body.

A plurality of first chip pads 211 provided on the first semiconductor device 210 may be connected to a plurality of upper connection pads 144 provided on the upper redistribution layer 140, through a plurality of chip connection members 212, respectively. The plurality of upper connection pads 144 may be electrically connected to the upper redistribution line patterns 141 and the upper redistribution via patterns 142 of the upper redistribution layer 140. The chip connecting member 212 may be, for example, a bump, a solder ball, or a conductive pillar.

An underfill material layer 230 surrounding the chip connection members 212 may be filled between the first semiconductor device 210 and the upper redistribution layer 140. The underfill material layer 230 may be formed of, for example, an epoxy resin formed by a capillary underfill method. In some embodiments, the underfill material layer 230 may be a non-conductive film (NCF).

The first semiconductor device 210 may include a logic chip and/or a memory chip. The logic chip may include, for example, an application processor (AP), a microprocessor, a central processing unit (CPU), a controller, an application-specific integrated circuit (ASIC), or the like. The first semiconductor device 210 may constitute AP/graphics processing unit (GPU)/CPU/system-on-chip (SoC) chips, a modem chip that supports communication between AP/GPU/CPU/SoC chips, and the like. Depending on the type of these logic chips, the semiconductor package 1 may be classified as a server-oriented semiconductor device or a mobile-oriented semiconductor device. In addition, the memory chip may include a volatile memory device such as dynamic random-access memory (DRAM) or static random-access memory (SRAM), or a non-volatile memory device such as flash memory.

At least one first semiconductor device 210 may be provided on the glass core interposer 100. The first semiconductor device 210 may include a logic chip and/or a memory chip. The logic chip may include, for example, an AP, a microprocessor, a CPU, a controller, an ASIC, or the like. The first semiconductor device 210 may include AP/graphics processing unit (GPU)/CPU/SoC chips, a modem chip that supports communication between AP/GPU/CPU/SoC chips, and the like. Depending on the type of these logic chips, the semiconductor package 1 may be classified as a server-oriented semiconductor device or a mobile-oriented semiconductor device. In addition, the memory chip may include a volatile memory device such as DRAM or SRAM, or a non-volatile memory device such as flash memory.

A lower redistribution layer 150 may be provided on the second lower-surface insulating layer 131B. The lower redistribution layer 150 may include lower redistribution insulating layers 153, a plurality of lower redistribution line patterns 151 arranged on at least some of the upper surfaces or lower surfaces of the lower redistribution insulating layers 153, and a plurality of lower redistribution via patterns 152 penetrating the lower redistribution insulating layers 153 and in contact with some of the plurality of lower redistribution line patterns 151. The lower redistribution via pattern 152 may have a tapered shape of which the horizontal width increases away from the glass core substrate 110. The plurality of lower redistribution line patterns 151 and the plurality of lower redistribution via patterns 152 may be collectively referred to as lower redistribution patterns. The description of the lower redistribution layer 150 is mostly similar to the description of the upper redistribution layer 140, and thus, detailed descriptions thereof will be omitted. However, the semiconductor package 1 according to some embodiments may not include the lower redistribution layer 150.

A plurality of external connection pads 154 may be provided on the lower surface of the lower redistribution layer 150. A plurality of external connection terminals 155 may be arranged on the lower surfaces of the plurality of external connection pads 154, respectively. An external electronic device, such as a printed circuit board, may be connected through the plurality of external connection terminals 155. A first passive device 156 may be provided in at least some of the plurality of external connection terminals 155. The first passive device 156 may be a surface-mount device (SMD).

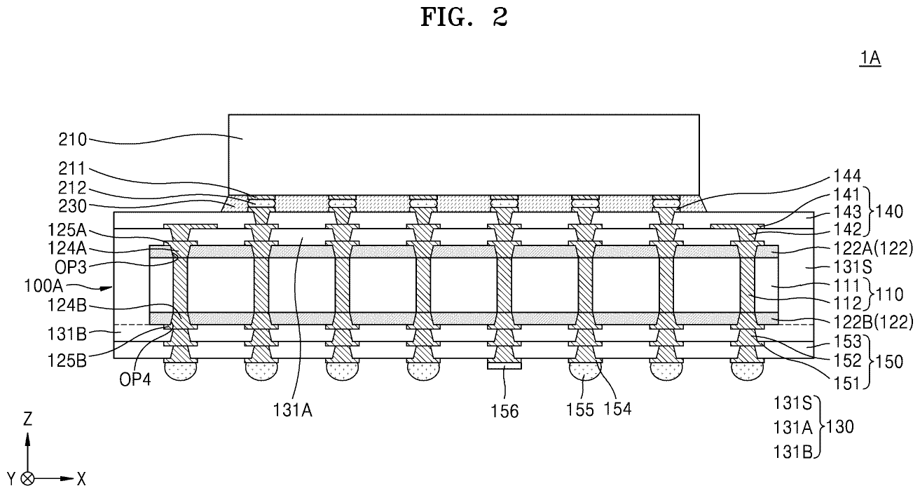

FIG. 2 is a cross-sectional view illustrating a semiconductor package 1A according to embodiments. Descriptions of similar or identical elements that are already provided above may be omitted.

Referring to FIG. 2, the semiconductor package 1A according to embodiments may include a glass core interposer 100A and the first semiconductor device 210 arranged on the glass core interposer 100A. The glass core interposer 100A may include the glass core substrate 110, a first insulating layer 122, the second insulating layer 130, and the upper redistribution layer 140. The glass core substrate 110 may include the glass body 111 and the through electrodes 112.

The first insulating layer 122 may include a first upper-surface insulating layer 122A and a first lower-surface insulating layer 122B. The first insulating layer 122 may cover the upper surface and the lower surface of the glass core substrate 110. The outer edge of the glass core substrate 110, the outer edge of the first upper-surface insulating layer 122A, and the outer edge of the first lower-surface insulating layer 122B may coincide with each other. That is, the planar area of the glass core substrate 110, the planar area of the first upper-surface insulating layer 122A, and the planar area of the first lower-surface insulating layer 122B may be identical to each other.

The second insulating layer 130 may surround the glass core substrate 110 and the first insulating layer 122. The second insulating layer 130 may include the second side-surface insulating layer 131S, the second upper-surface insulating layer 131A, and the second lower-surface insulating layer 131B. The second upper-surface insulating layer 131A may cover the upper surface of the first upper-surface insulating layer 122A, and the second lower-surface insulating layer 131B may cover the lower surface of the first lower-surface insulating layer 122B. The second side-surface insulating layer 131S may simultaneously cover the side surface of the first upper-surface insulating layer 122A, the side surface of the first lower-surface insulating layer 122B, and the side surface of the glass core substrate 110.

The side surface of the second insulating layer 130 may be spaced apart from the side surface of the glass core substrate 110. That is, the planar area of the second insulating layer 130 may be larger than the planar area of the first insulating layer 122 and the planar area of the glass core substrate 110. The side surface of the second insulating layer 130 may be spaced laterally from the side surface of the glass core substrate 110 by 30 μm to 500 μm. That is, the horizontal width of the second side-surface insulating layer 131S may be 30 μm to 500 μm.

In another embodiment, the side surface of the second side-surface insulating layer 131S, the glass core substrate 110, and the side surface of the first insulating layer 122 may be vertically aligned with each other. That is, the planar area of the glass core substrate 110, the planar area of the first insulating layer 122, and the planar area of the second insulating layer 130 may be identical to each other.

The second side-surface insulating layer 131S, the second upper-surface insulating layer 131A, and the second lower-surface insulating layer 131B may have the same material composition. The second side-surface insulating layer 131S and the second upper-surface insulating layer 131A may be formed integrally with each other, and the second lower-surface insulating layer 131B may be formed separately from the second side-surface insulating layer 131S and the second upper-surface insulating layer 131A. Alternatively, the second lower-surface insulating layer 131B may be simultaneously formed integrally with the second side-surface insulating layer 131S and the second upper-surface insulating layer 131A.

The first insulating layer 122 may be made of a non-photoimageable dielectric. For example, the first insulating layer 122 may be formed of a silicon oxide film, a silicon nitride film, or a silicon oxynitride film. However, the first insulating layer 122 may not include a filler. The second insulating layer 130 may be made of an insulating material including a filler. For example, the second insulating layer 130 may be a thermosetting resin such as an epoxy resin, a thermoplastic resin such as a polyimide, or such a resin with an inorganic filler or/and glass fiber (glass cloth or glass fabric) mixed as a filler. For example, ABF and prepreg may be used for the second insulating layer 130.

A third opening OP3 may penetrate the first upper-surface insulating layer 122A. The upper core via 124A may be provided inside the third opening OP3. The upper core via 124A may penetrate the first upper-surface insulating layer 122A. The upper core via 124A may be in contact with the upper end of the through electrode 112. The upper end of the through electrode 112 may have the same vertical level as the upper surface of the glass core substrate 110. The vertical height of the upper core via 124A may be substantially equal to the vertical thickness of the first upper-surface insulating layer 122A. The side surface of the upper core via 124A may be in contact with the first upper-surface insulating layer 122A.

A fourth opening OP4 may penetrate the first lower-surface insulating layer 122B. The lower core via 124B may be provided inside the fourth opening OP4. The lower core via 124B may penetrate the first lower-surface insulating layer 122B. The lower core via 124B may be in contact with the lower end of the through electrode 112. The lower end of the through electrode 112 may have the same vertical level as the lower surface of the glass core substrate 110. The vertical height of the lower core via 124B may be substantially equal to the vertical thickness of the first lower-surface insulating layer 122B. The side surface of the lower core via 124B may be in contact with the first lower-surface insulating layer 122B.

The upper core pad 125A may be provided at one end of the upper core via 124A. The upper core pad 125A and the upper core via 124A may be formed as one body. The upper core pad 125A may be provided on the first upper-surface insulating layer 122A. Similarly, the lower core pad 125B may be provided at one end of the lower core via 124B. The lower core pad 125B and the lower core via 124B may be formed as one body. The lower core pad 125B may be placed on the first lower-surface insulating layer 122B.

The first insulating layer 122 may include a polymer, a dielectric film, etc. The first insulating layer 122 may be made of a photoimageable dielectric or a non-photoimageable dielectric. In a case in which the first insulating layer 122 is made of a photoimageable dielectric, for example, the first insulating layer 122 may include a photosensitive polymer. The photosensitive polymer may be formed of at least one of, for example, a photosensitive polyimide, polybenzoxazole, a phenol-based polymer, and a benzocyclobutene-based polymer. Alternatively, the first insulating layer 122 may include lead oxide (PbO), polyhydroxystyrene (PHS), or the like including a photosensitizer. In a case in which the first insulating layer 122 is made of a non-photoimageable dielectric, for example, the first insulating layer 122 may be formed of a silicon oxide film, a silicon nitride film, or a silicon oxynitride film. The first insulating layer 122 may be formed by a vapor deposition process, a spin coating process, or the like. However, the first insulating layer 122 may not include a filler.

The second insulating layer 130 may be made of an insulating material including a filler. For example, the second insulating layer 130 may be a thermosetting resin such as an epoxy resin, a thermoplastic resin such as a polyimide, or such a resin with an inorganic filler or/and glass fiber (glass cloth or glass fabric) mixed as a filler. For example, ABF and prepreg may be used for the second insulating layer 130.

In the semiconductor package 1A according to embodiments, the first insulating layer 122 that does not include a filler is arranged between the second insulating layer 130 and the glass core substrate 110. Because the first insulating layer 122 does not include a filler, the adhesion between the first insulating layer 122 and the glass core substrate 110 may be secured. In addition, even in a case in which the second insulating layer 130 includes a filler, the adhesion between the second insulating layer 130 and the first insulating layer 122 is relatively greater than the adhesion between the second insulating layer 130 and the glass core substrate 110, and thus, the adhesion between the second insulating layer 130 and the first insulating layer 122 may be sufficiently secured. Because the second insulating layer 130 surrounds the side surface of the glass core substrate 110, the second insulating layer 130 may protect the glass core substrate 110, and the possibility of the first insulating layer 122 and the glass core substrate 110 being peeled off may be further reduced. Thus, the reliability of the semiconductor package 1A according to embodiments may be improved.

The upper redistribution layer 140 may be provided on the second upper-surface insulating layer 131A. The upper redistribution layer 140 may include the upper redistribution insulating layers 143, the plurality of upper redistribution line patterns 141 arranged on at least some of the upper surfaces or lower surfaces of the upper redistribution insulating layers 143, and the plurality of upper redistribution via patterns 142 penetrating the upper redistribution insulating layers 143 and in contact with some of the plurality of upper redistribution line patterns 141. The upper redistribution via pattern 142 may have a tapered shape of which the horizontal width increases away from the glass core substrate 110. The plurality of upper redistribution line patterns 141 and the plurality of upper redistribution via patterns 142 may be collectively referred to as upper redistribution patterns. At least some of the plurality of upper redistribution via patterns 142 may be connected to a plurality of upper core pads 125A. At least some of the plurality of upper redistribution via patterns 142 may penetrate the second upper-surface insulating layer 131A to electrically connect the plurality of upper redistribution line patterns 141 to the upper core pads 125A.

The lower redistribution layer 150 may be provided on the second lower-surface insulating layer 131B. The lower redistribution layer 150 may include the lower redistribution insulating layers 153, the plurality of lower redistribution line patterns 151 arranged on at least some of the upper surfaces or lower surfaces of the lower redistribution insulating layers 153, and the plurality of lower redistribution via patterns 152 penetrating the lower redistribution insulating layers 153 and in contact with some of the plurality of lower redistribution line patterns 151. At least some of the plurality of lower redistribution via patterns 152 may be connected to a plurality of lower core pads 125B. At least some of the plurality of lower redistribution via patterns 152 may penetrate the second lower-surface insulating layer 131B to electrically connect the plurality of lower redistribution line patterns 151 to the lower core pads 125B. The description of the lower redistribution layer 150 is mostly similar to the description of the upper redistribution layer 140 provided above, and thus, detailed descriptions thereof will be omitted.

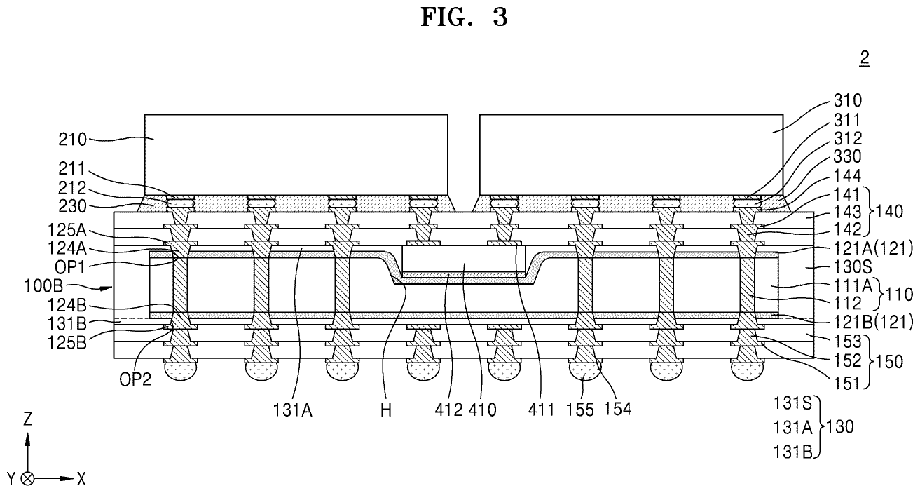

FIG. 3 is a cross-sectional view illustrating a semiconductor package 2 according to embodiments. Descriptions of similar or identical elements that are already provided above may be omitted.

Referring to FIG. 3, the semiconductor package 2 according to embodiments may include a glass core interposer 100B, and the first semiconductor device 210 and a second semiconductor device 310 both arranged on the glass core interposer 100B. The glass core interposer 100B may include the glass core substrate 110, the first insulating layer 121, the second insulating layer 130, the upper redistribution layer 140, and a bridge chip 410. The glass core substrate 110 may include a glass body 111A and the through electrodes 112.

The glass body 111A may have the shape of a quadrangular flat plate, and a part of the upper surface of the glass body 111A may have a concave portion H that is concave inward from (e.g., recessed into) the upper surface of the glass body 111A. The first upper-surface insulating layer 121A may cover the upper surface of the glass core substrate 110 along the shape of the concave portion H. The bridge chip 410 may be located inside the concave portion H of which the surface is covered by the first upper-surface insulating layer 121A. The bridge chip 410 may be attached to the first upper-surface insulating layer 121A inside the concave portion H, through an adhesive film 412.

The second upper-surface insulating layer 131A may fill a gap between the bridge chip 410 and the concave portion H and simultaneously cover the upper surface of the first upper-surface insulating layer 121A. The vertical level of the upper surface of the second upper-surface insulating layer 131A may be substantially the same as or lower than the vertical level of the upper surface of the bridge chip 410 relative to the lower redistribution layer 150. As used herein, vertical levels or distances are relative to the lower redistribution layer 150 in a vertical (e.g., z-) direction.

The bridge chip 410 may include a plurality of connection wiring patterns and a chip pad 411. The bridge chip 410 may be a semiconductor substrate. For example, the bridge chip 410 may include silicon (Si).

The plurality of connection wiring patterns may be formed in the bridge chip 410 through a wiring process for a typical semiconductor device. The plurality of connection wiring patterns may include connection line wirings forming a single layer, but are not limited thereto. In some embodiments, the plurality of connecting wiring patterns may include connecting line wirings forming two or more layers, and via plugs connecting between the connecting line wirings of different layers, and an inter-wiring insulating layer may be formed between the connecting line wiring and the via plug. The bridge chip 410 may not include individual electronic devices, but may include only wirings. The chip pad 411 may connect the bridge chip 410 to the upper redistribution patterns of the upper redistribution layer 140.

For example, transmission of power signals, ground signals, control signals, clock signals, and the like from the plurality of external connection terminals 155 to each of the first semiconductor device 210 and the second semiconductor device 310, and transmission and/or reception of data between each of the first semiconductor device 210 and the second semiconductor device 310, and the plurality of external connection terminals 155 may be performed through the lower redistribution line patterns 151 and the lower redistribution via patterns 152 of the lower redistribution layer 150, the through electrodes 112, and the upper redistribution line patterns 141 and the upper redistribution via patterns 142 of the upper redistribution layer 140.

On the contrary, for example, data transmission and/or reception between the first semiconductor device 210 and the second semiconductor device 310, signal transmission for clock synchronization between the first semiconductor device 210 and the second semiconductor device 310, and the like may be performed only through the upper redistribution line patterns 141 and the upper redistribution via patterns 142 of the upper redistribution layer 140, and the bridge chip 410 without using the lower redistribution layer 150.

The plurality of first chip pads 211 provided on the first semiconductor device 210 may be connected to some of the plurality of upper connection pads 144 provided on the upper redistribution layer 140, through the plurality of chip connection members 212, respectively. A plurality of second chip pads 311 provided on the second semiconductor device 310 may be connected to the rest of the plurality of upper connection pads 144 provided on the upper redistribution layer 140, through a plurality of chip connection members 312, respectively. The chip connecting member 312 may be, for example, a bump, a solder ball, or a conductive pillar.

An underfill material layer 330 surrounding the chip connection members 312 may be filled between the second semiconductor device 310 and the upper redistribution layer 140. The underfill material layer 330 may be formed of, for example, an epoxy resin formed by a capillary underfill method. In some embodiments, the underfill material layer 330 may be an NCF.

The second semiconductor device 310 may include a logic chip and/or a memory chip. The description of the second semiconductor device 310 is mostly similar to the description of the first semiconductor device 210, and thus, detailed descriptions thereof will be omitted.

The first insulating layer 121 may include a polymer, a dielectric film, etc. The first insulating layer 121 may be made of a photoimageable dielectric or a non-photoimageable dielectric. In a case in which the first insulating layer 121 is made of a photoimageable dielectric, for example, the first insulating layer 121 may include a photosensitive polymer. The photosensitive polymer may be formed of at least one of, for example, a photosensitive polyimide, polybenzoxazole, a phenol-based polymer, and a benzocyclobutene-based polymer. Alternatively, the first insulating layer 121 may include lead oxide (PbO), polyhydroxystyrene (PHS), or the like including a photosensitizer. In a case in which the first insulating layer 121 is made of a non-photoimageable dielectric, for example, the first insulating layer 121 may be formed of a silicon oxide film, a silicon nitride film, or a silicon oxynitride film. The first insulating layer 121 may be formed by a vapor deposition process, a spin coating process, or the like. However, the first insulating layer 121 may not include a filler.

The second insulating layer 130 may be made of an insulating material including a filler. For example, the second insulating layer 130 may be a thermosetting resin such as an epoxy resin, a thermoplastic resin such as a polyimide, or such a resin with an inorganic filler or/and glass fiber (glass cloth or glass fabric) mixed as a filler. For example, ABF and prepreg may be used for the second insulating layer 130.

The upper core via 124A may simultaneously penetrate the first upper-surface insulating layer 121A and the second upper-surface insulating layer 131A. The lower core via 124B may simultaneously penetrate the first lower-surface insulating layer 121B and the second lower-surface insulating layer 131B. The description of the upper core via 124A and the lower core via 124B is mostly similar to the description of the upper core via 124A and the lower core via 124B of the semiconductor package 1 of FIG. 1, and thus, detailed descriptions thereof will be omitted.

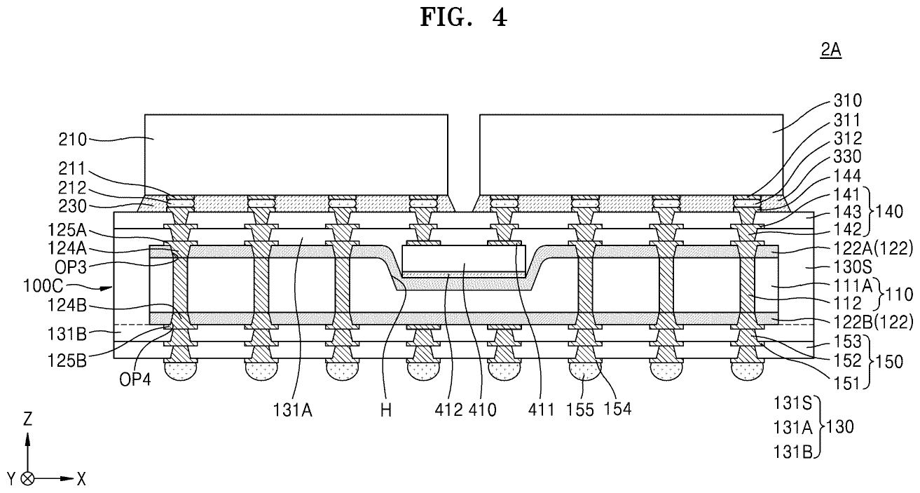

FIG. 4 is a cross-sectional view illustrating a semiconductor package 2A according to embodiments. Descriptions of similar or identical elements that are already provided above may be omitted.

Referring to FIG. 4, the semiconductor package 2A according to embodiments may include a glass core interposer 100C, and the first semiconductor device 210 and the second semiconductor device 310 both arranged on the glass core interposer 100C. The glass core interposer 100C may include the glass core substrate 110, the first insulating layer 122, the second insulating layer 130, the upper redistribution layer 140, and the bridge chip 410. The glass core substrate 110 may include the glass body 111A and the through electrodes 112.

The glass body 111A may have the shape of a quadrangular flat plate, and a part of the upper surface of the glass body 111A may have the concave portion H that is concave inward from the upper surface. The first upper-surface insulating layer 121A may cover the upper surface of the glass core substrate 110 along the shape of the concave portion H. The bridge chip 410 may be located inside the concave portion H of which the surface is covered by the first upper-surface insulating layer 121A. The bridge chip 410 may be attached to the first upper-surface insulating layer 121A inside the concave portion H, through the adhesive film 412.

The second upper-surface insulating layer 131A may fill a gap between the bridge chip 410 and the concave portion H and simultaneously cover the upper surface of the first upper-surface insulating layer 121A. The vertical level of the upper surface of the second upper-surface insulating layer 131A may be higher than the vertical level of the upper surface of the bridge chip 410.

The first insulating layer 122 may be made of a non-photoimageable dielectric. For example, the first insulating layer 122 may be formed of a silicon oxide film, a silicon nitride film, or a silicon oxynitride film. However, the first insulating layer 122 may not include a filler. The second insulating layer 130 may be made of an insulating material including a filler. For example, the second insulating layer 130 may be a thermosetting resin such as an epoxy resin, a thermoplastic resin such as a polyimide, or such a resin with an inorganic filler or/and glass fiber (glass cloth or glass fabric) mixed as a filler. For example, ABF and prepreg may be used for the second insulating layer 130.

The upper core via 124A may penetrate the first upper-surface insulating layer 122A. The lower core via 124B may penetrate the first lower-surface insulating layer 122B. The description of the upper core via 124A and the lower core via 124B is mostly similar to the description of the upper core via 124A and the lower core via 124B of the semiconductor package 1A of FIG. 2, and thus, detailed descriptions thereof will be omitted.

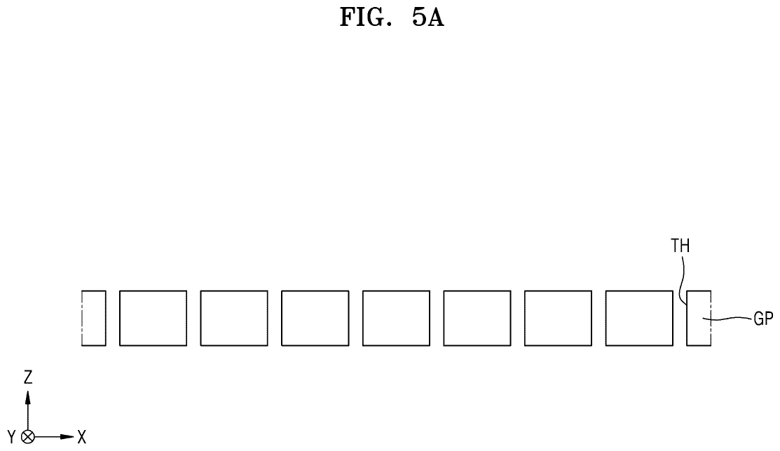

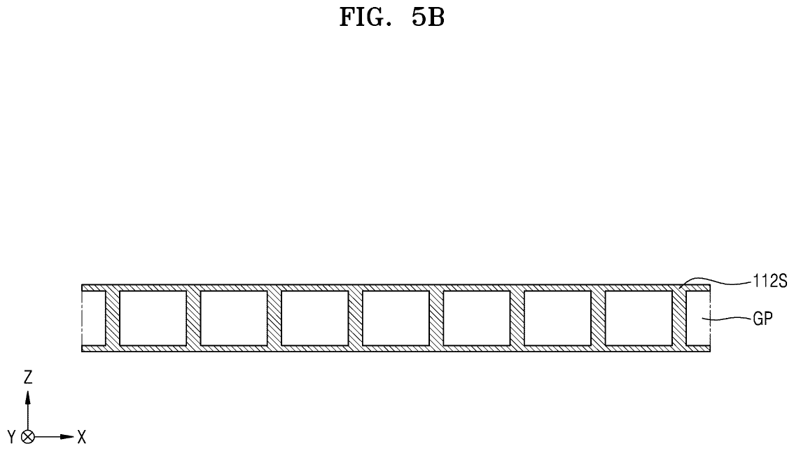

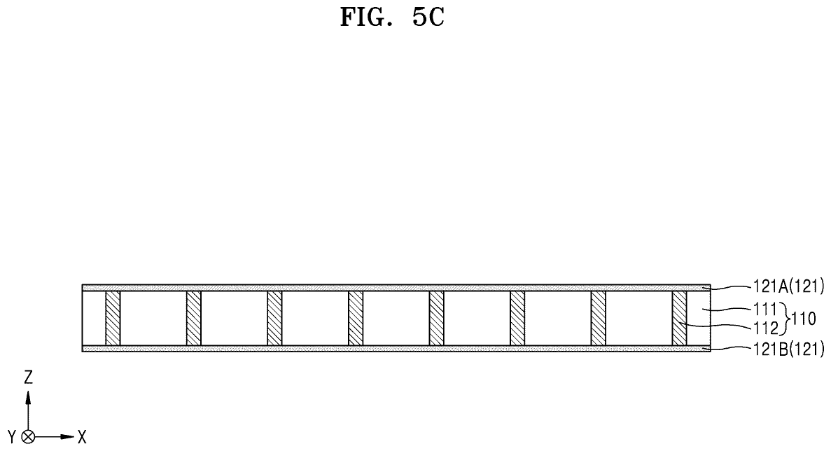

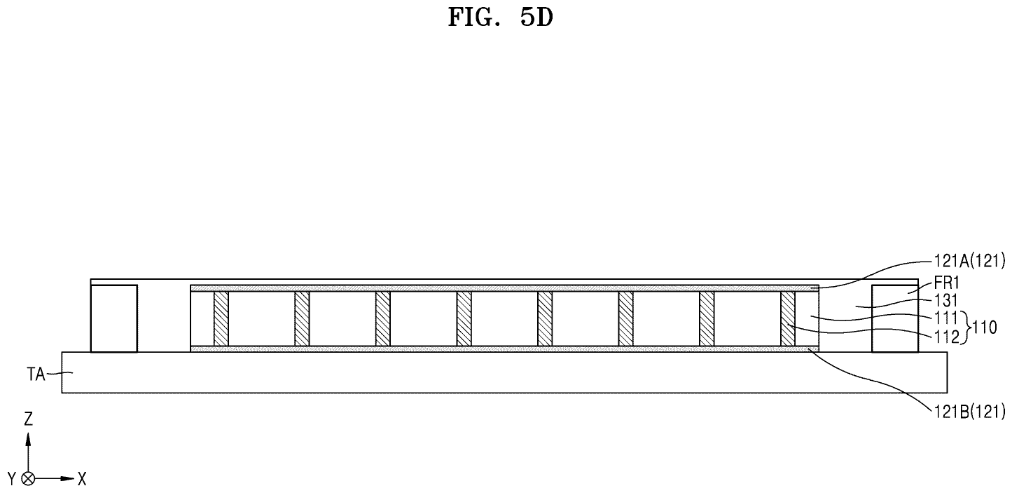

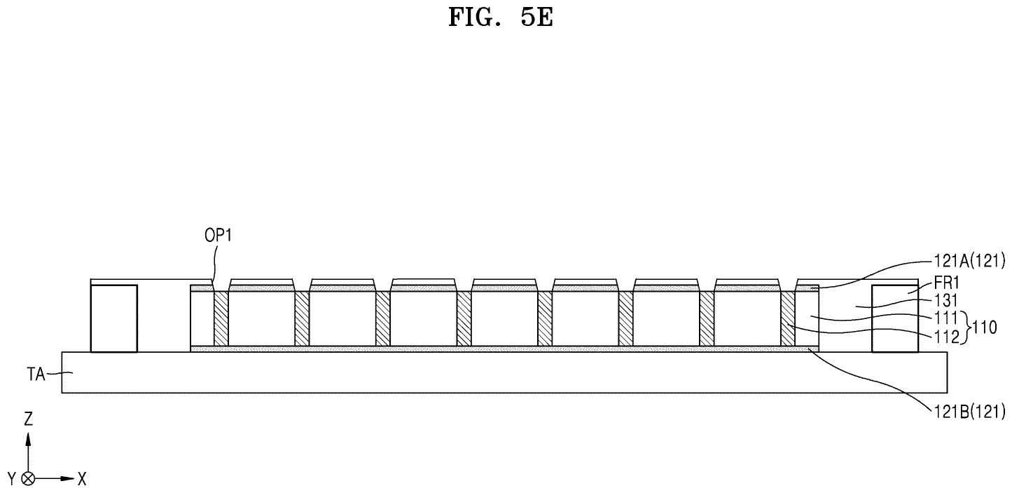

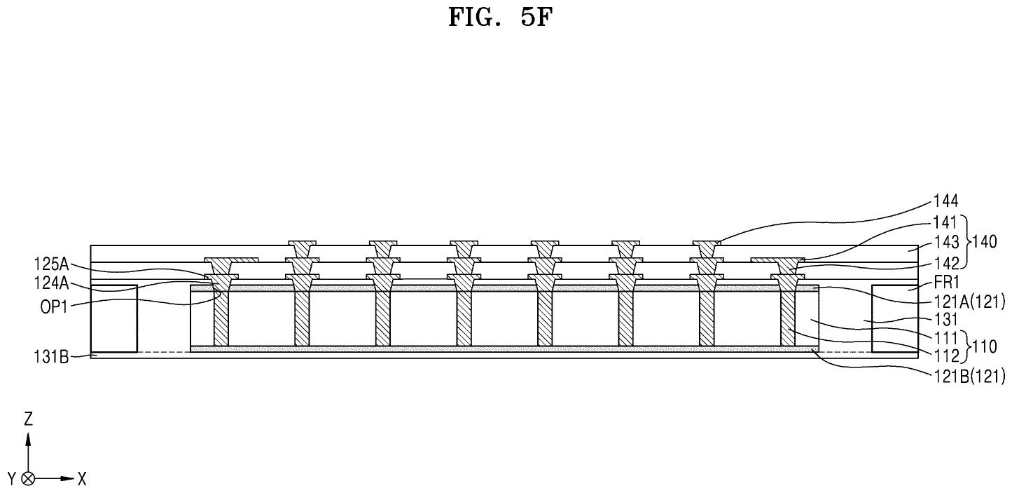

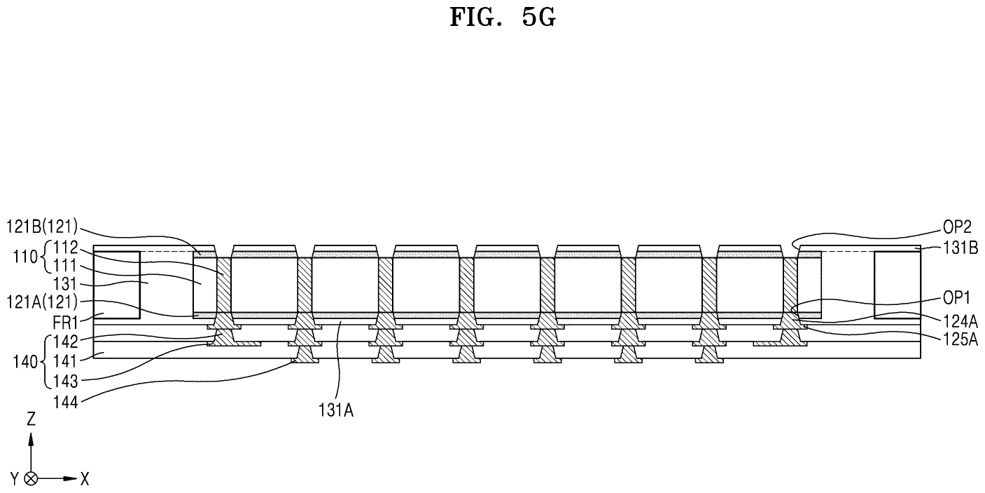

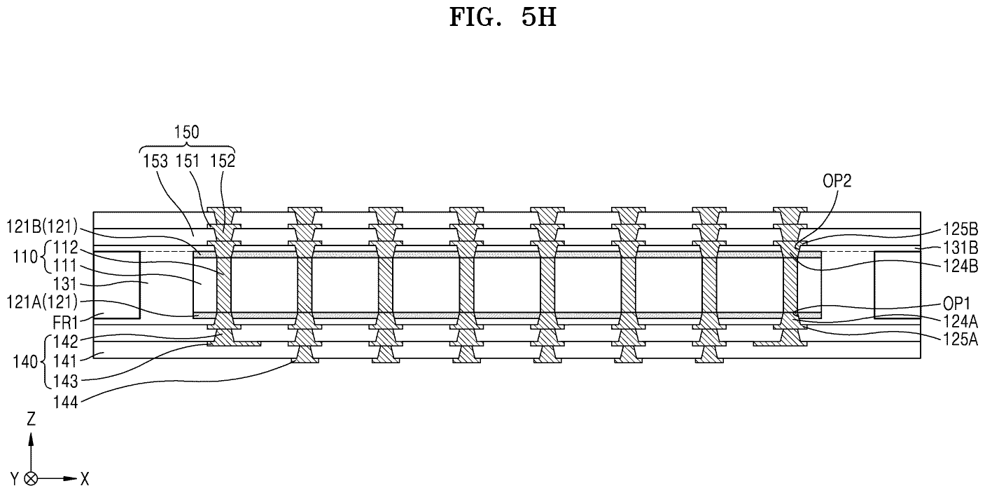

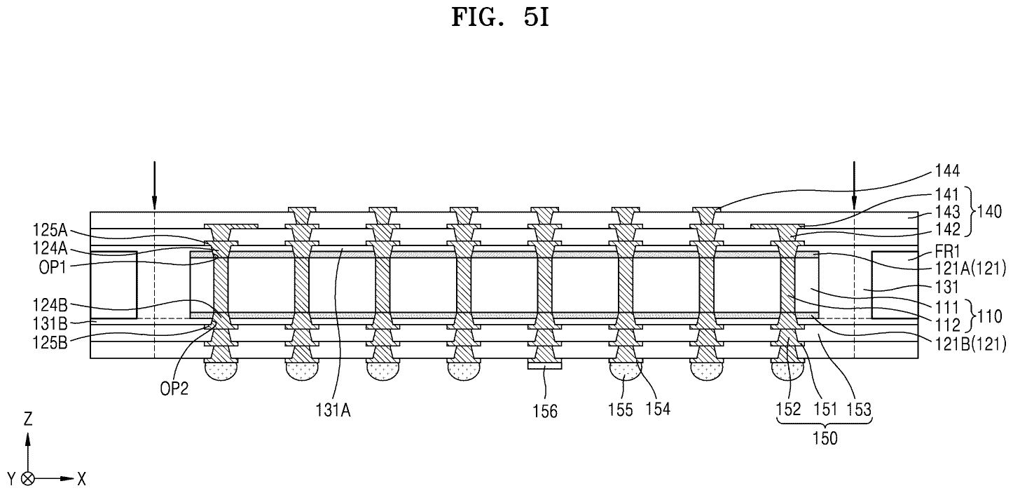

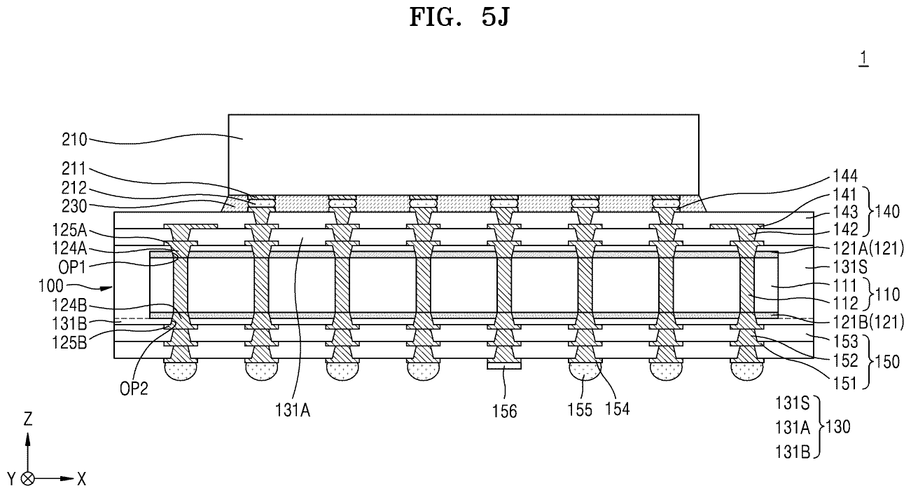

FIGS. 5A to 5J are cross-sectional views illustrating a process of manufacturing the semiconductor package 1, according to embodiments.

Referring to FIG. 5A, a glass panel GP is prepared. The glass panel GP may be sized to include a plurality of glass core substrates. Accordingly, the glass panel GP may be individualized into a plurality of unit glass core substrates after a process of an initial glass core substrate is completed. A plurality of through holes TH are formed in the glass panel GP for forming through electrodes. The through holes TH may be formed through a laser drilling process or an etching process. However, the process of forming the through holes TH is not limited to the above processes.

Referring to FIG. 5B, an adhesive layer may be formed inside the through holes TH and on the upper surface and the lower surface of the glass panel GP in a result of the process of FIG. 5A. The adhesive layer may be a conductive layer or a non-conductive layer. For example, the adhesive layer may include a metal layer. After the formation of the adhesive layer, a metal layer 112S for through electrodes is formed. For example, a Cu layer is formed on the adhesive layer through electroplating. In addition, in a case in which the adhesive layer is not a metal layer, a process of forming a separate seed metal layer may be performed before the process of forming the metal layer 112S for through electrodes. The metal layer 112S for through electrodes may fill the inside of the through holes TH and may be formed on the upper surface and the lower surface of the glass panel GP.

Referring to FIG. 5C, thereafter, through a grinding and/or polishing process, the metal layer 112S for through electrodes on the upper surface and the lower surface of the glass panel GP is removed to form the through electrodes 112 inside the through holes TH. Through the formation of the through electrodes 112, a plurality of glass core substrates 110 may be completed on the glass panel GP. After forming the through electrodes 112 inside the through holes TH, the first upper-surface insulating layer 121A and the first lower-surface insulating layer 121B may be formed on the upper surface and the lower surface of the glass core substrate 110, respectively. Thereafter, the glass panel GP may be individualized into glass core substrates 110 through a sawing process.

Referring to FIG. 5D, a result of the process of FIG. 5C may be arranged inside a frame FR1 having a panel size. A tape TA may be attached to the lower surface of the frame FR1. The tape TA may be sized to cover the entire frame FR1. The panel size may correspond to the sum of the sizes of a plurality of package substrates. The frame FR1 may include a plurality of quadrangular grids, for example, frame grids in the shape of a quadrangular ring. The result of the process of FIG. 5C may be arranged inside the frame FR1, and a second insulating layer 131 may cover the glass core substrate 110 and the first insulating layer 121. The second insulating layer 131 may be attached in a film form or dispensed in a liquid form. The second insulating layer 131 may cover the first insulating layer 121 and the frame FR1.

Referring to FIG. 5E, a plurality of first openings OP1 that simultaneously penetrate the first upper-surface insulating layer 121A and a second insulating layer 131 may be formed. The first opening OP1 may expose one end of the through electrode 112. The first opening OP1 may be formed by laser or etching.

Referring to FIG. 5F, the upper core via 124A and the upper core pad 125A may be provided in the first opening OP1 through a process such as electroplating. Thereafter, the upper redistribution layer 140 may be formed through a redistribution process. The upper redistribution layer 140 may be formed by sequentially stacking each upper redistribution insulating layers 143, and the upper redistribution line patterns 141 or the upper redistribution via patterns 142, and the upper redistribution line patterns 141. In addition, the second lower-surface insulating layer 131B may be formed on a surface on the opposite side of the upper redistribution layer 140 from which the tape TA has been removed. The second lower-surface insulating layer 131B may have the same material composition as the second insulating layer 131.

Referring to FIG. 5G, a plurality of second openings OP2 that simultaneously penetrate the first lower-surface insulating layer 121B and the second lower-surface insulating layer 131B may be formed. The second opening OP2 may expose one end of the through electrode 112. The second opening OP2 may be formed by laser or etching.

Referring to FIG. 5H, the lower core via 124B and the lower core pad 125B may be provided in the second opening OP2 through a process such as electroplating. Thereafter, the lower redistribution layer 150 may be formed through a redistribution process. The process of the lower redistribution layer 150 is similar to the process of the upper redistribution layer 140.

Referring to FIG. 5I, a lateral portion of the second insulating layer 131 may be removed. The frame FR1 that was located on a side of the glass core substrate 110 during the manufacturing process may be removed by cutting the portion of the second insulating layer 131 indicated by the dashed lines and the arrow. Thereafter, the external connection terminal 155 and the passive device 156 may be arranged on each of the plurality of external connection pads 154. The order of the process of cutting the second insulating layer 131 and the process of arranging the external connection terminal 155 and the passive device 156 may be different from the above.

Referring to FIG. 5J, the first semiconductor device 210 may be arranged on the upper redistribution layer 140. The first chip pad 211 of the first semiconductor device 210 may be connected through the upper connection pad 144 and the first chip connection member 212. Thereafter, the underfill material layer 230 may be arranged between the first semiconductor device 210 and the upper surface of the upper redistribution layer 140 by, for example, a capillary underfill method. Through these processes, the semiconductor package 1 according to embodiments may be manufactured.

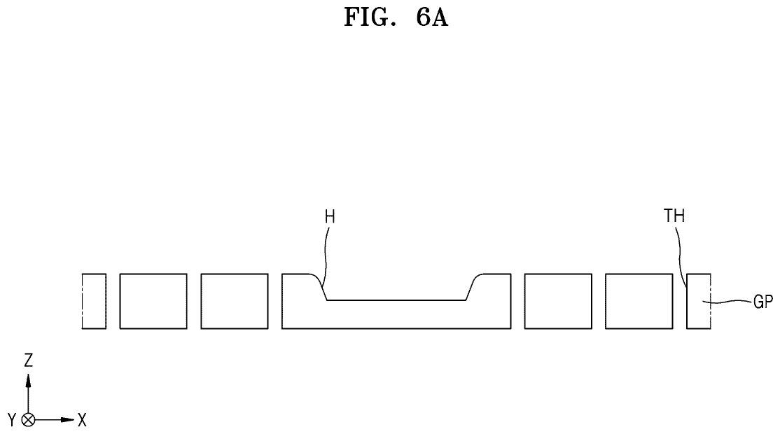

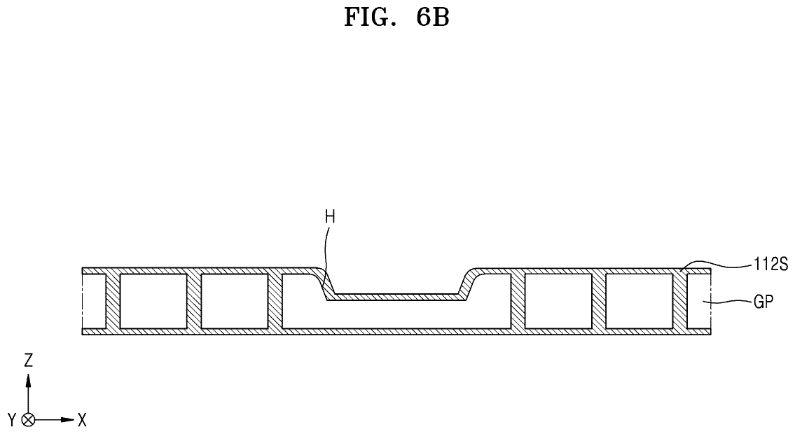

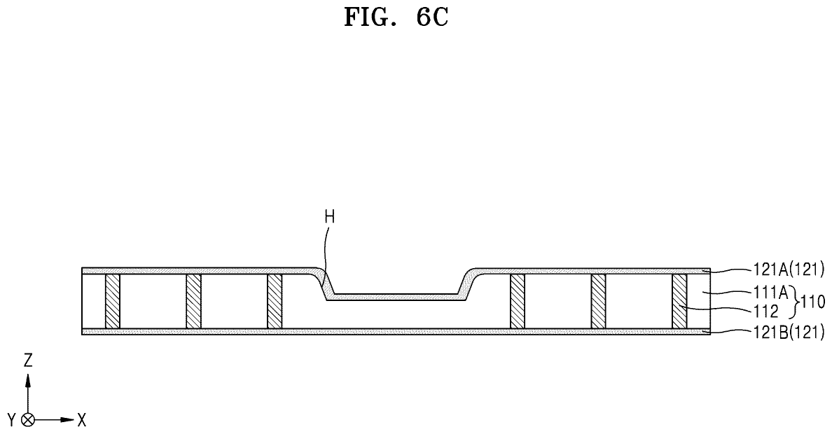

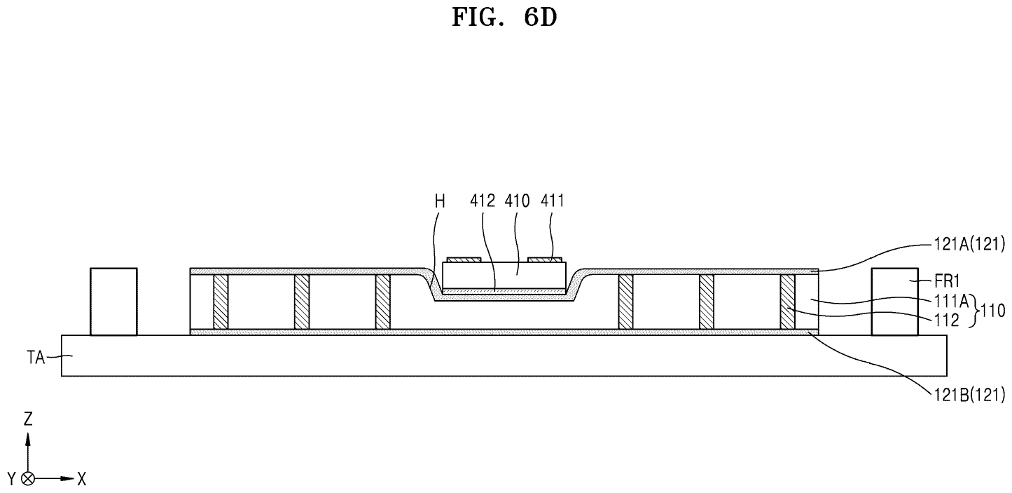

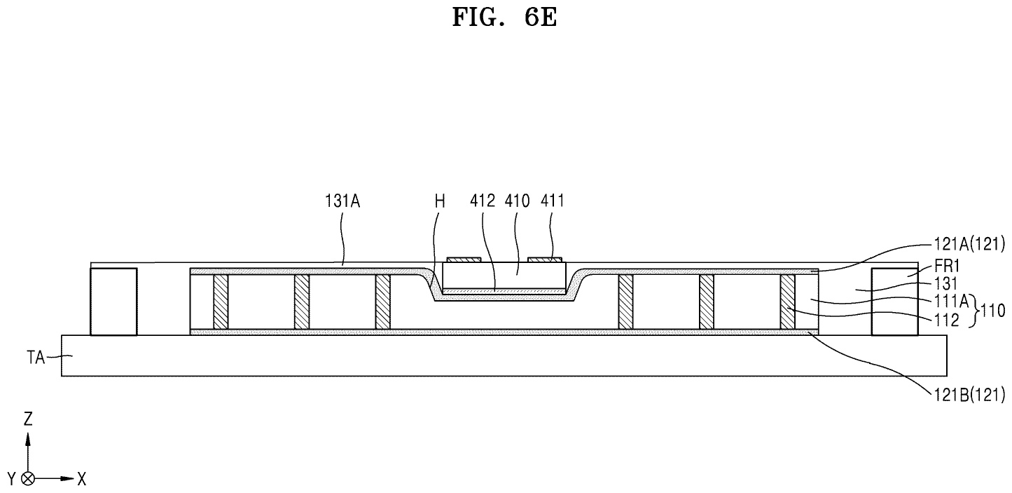

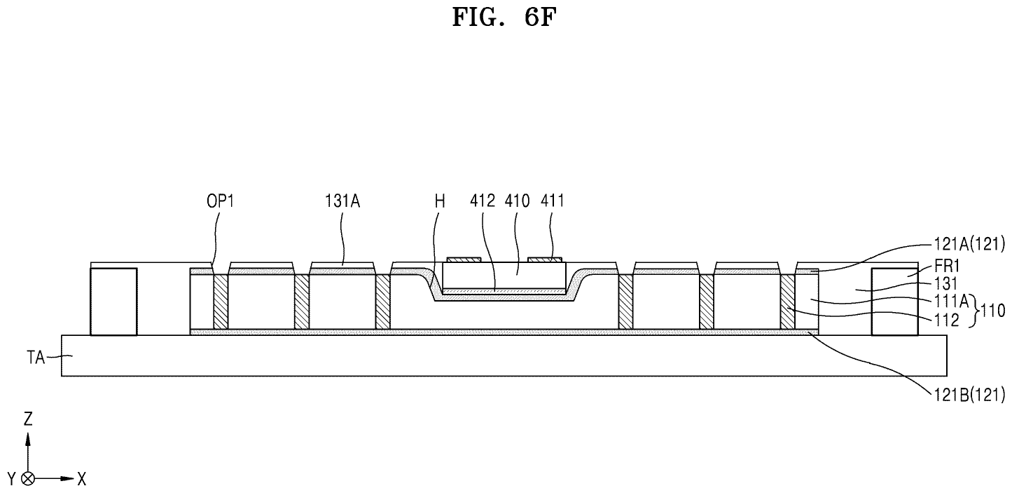

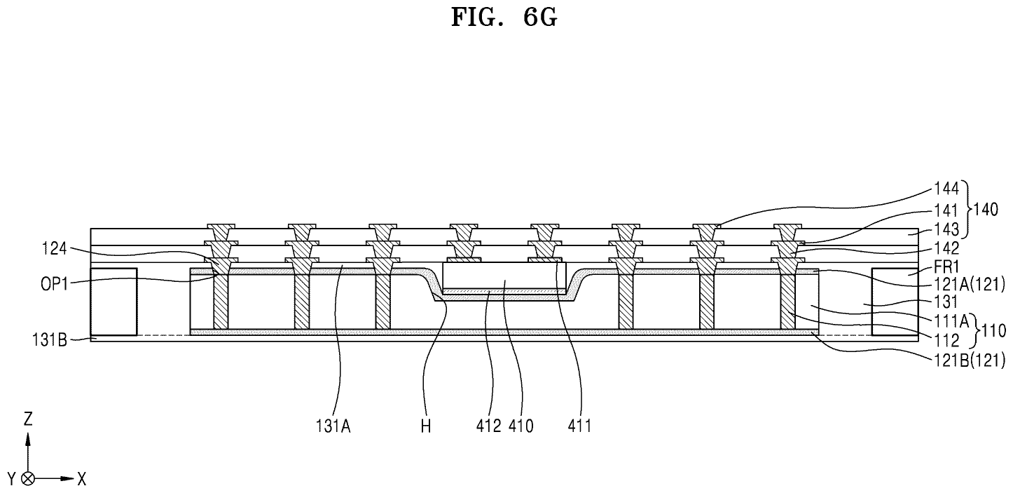

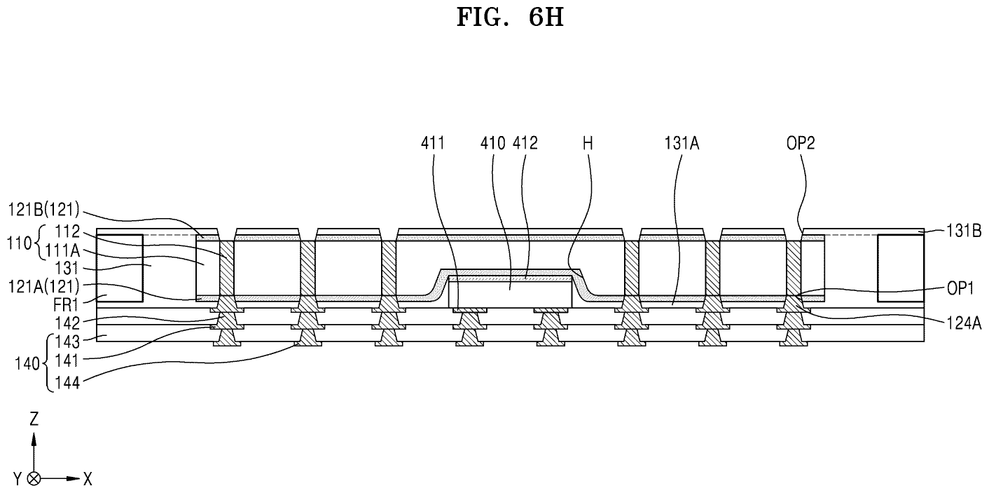

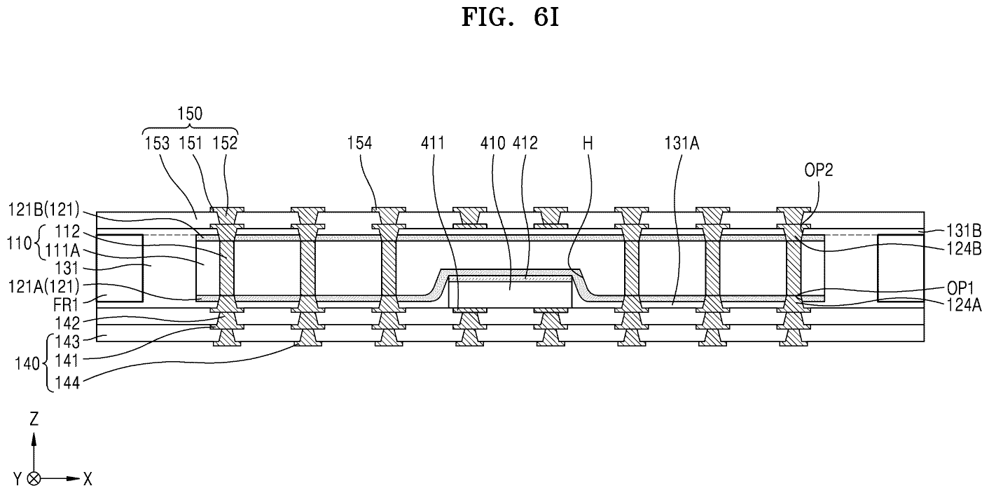

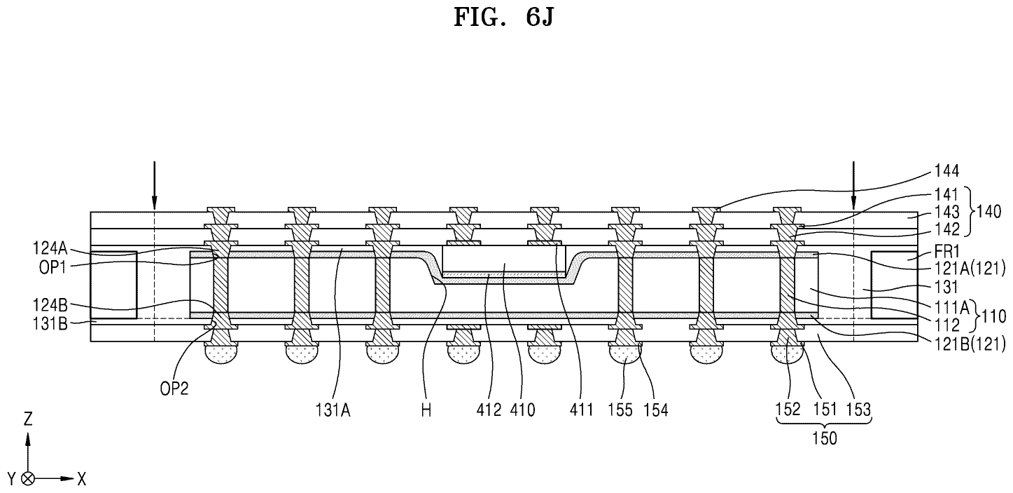

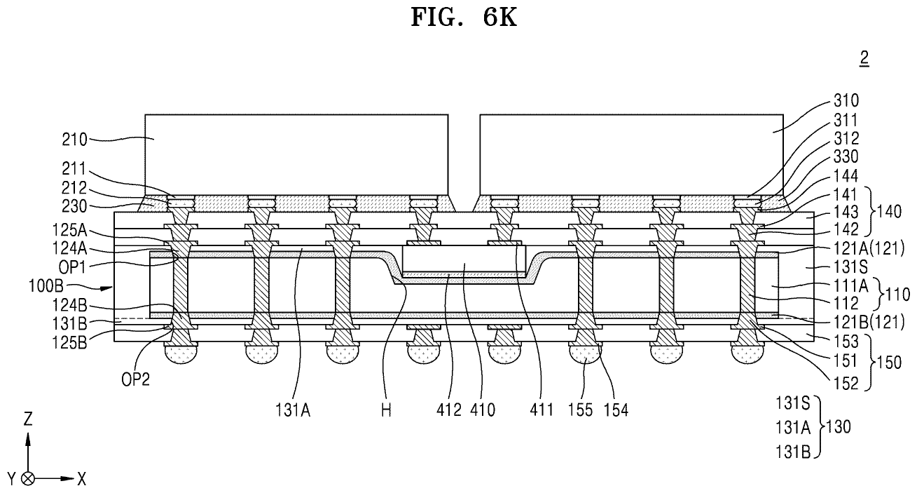

FIGS. 6A to 6K are cross-sectional views illustrating a process of manufacturing the semiconductor package 2, according to embodiments. Descriptions that are already provided above may be omitted.

Referring to FIG. 6A, a glass panel GP that is sized to include a plurality of glass core substrates is prepared. A plurality of through holes TH for forming through electrodes and the concave portion H are formed in the glass panel GP. The through holes TH and the concave portion H may be formed through a laser drilling process or an etching process. The concave portion H refers to a groove that is concave inward from the upper surface of the glass panel GP but does not penetrate the glass panel GP. In another embodiment, the concave portion H may penetrate the glass panel GP and may be formed together with the through holes TH.

Referring to FIG. 6B, an adhesive layer may be formed inside the through holes TH and on the upper surface and the lower surface of the glass panel GP in a result of the process of FIG. 6A. After the formation of the adhesive layer, the metal layer 112S for through electrodes is formed. For example, a Cu layer is formed on the adhesive layer through electroplating. In addition, in a case in which the adhesive layer is not a metal layer, a process of forming a separate seed metal layer may be performed before the process of forming the metal layer 112S for through electrodes. The metal layer 112S for through electrodes may fill the inside of the through holes TH and may be formed on the upper surface and the lower surface of the glass panel GP along the shape of the concave portion H. In another embodiment, the concave portion H may penetrate the glass panel GP, and an adhesion prevention layer may be arranged inside the concave portion H to prevent formation of an adhesive layer. Through this, the metal layer 112S for through electrodes may not be formed inside the concave portion H.

Referring to FIG. 6C, thereafter, through a grinding and/or polishing process, the metal layer 112S for through electrodes on the upper surface and the lower surface of the glass panel GP is removed to form the through electrodes 112 inside the through holes TH. Through the formation of the through electrodes 112, a plurality of glass core substrates 110 may be completed on the glass panel GP. After forming the through electrodes 112 inside the through holes TH, the first upper-surface insulating layer 121A and the first lower-surface insulating layer 121B may be formed on the upper surface and the lower surface of the glass core substrate 110, respectively. Thereafter, the glass panel GP may be individualized into glass core substrates 110 through a sawing process.

Referring to FIG. 6D, a result of the process of FIG. 6C may be arranged inside a frame FR1 having a panel size. A tape TA may be attached to the lower surface of the frame FR1. The result of the process of FIG. 6C may be arranged inside the frame FR1, and the bridge chip 410 may be arranged on the glass core substrate 110. The bridge chip 410 has the chip pad 411 on one side thereof and the adhesive film 412 on the opposite side, and thus, the adhesive film 412 may be attached to the first upper-surface insulating layer 121A located in the concave portion H.

Referring to FIG. 6E, the second insulating layer 131 may cover the glass core substrate 110 and the first insulating layer 121. The second insulating layer 131 may be attached in a film form or dispensed in a liquid form. A second insulating layer 1301 may cover the first insulating layer 121 and the frame FR1. The vertical level of the upper surface of the second upper-surface insulating layer 131A may be equal to or lower than the vertical level of the upper surface of the bridge chip 410.

Referring to FIG. 6F, a plurality of first openings OP1 that simultaneously penetrate the first upper-surface insulating layer 121A and the second insulating layer 131 may be formed. The first opening OP1 may expose one end of the through electrode 112. The first opening OP1 may be formed by laser or etching.

Referring to FIG. 6G, the upper core via 124A and the upper core pad 125A may be provided in the first opening OP1 through a process such as electroplating. Thereafter, the upper redistribution layer 140 may be formed through a redistribution process. In addition, the second lower-surface insulating layer 131B may be formed on a surface on the opposite side of the upper redistribution layer 140 from which the tape TA has been removed. The second lower-surface insulating layer 131B may have the same material composition as the second insulating layer 131.

Referring to FIG. 6H, a plurality of second openings OP2 that simultaneously penetrate the first lower-surface insulating layer 121B and the second lower-surface insulating layer 131B may be formed. The second opening OP2 may expose one end of the through electrode 112. The second opening OP2 may be formed by laser or etching.

Referring to FIG. 6I, the lower core via 124B and the lower core pad 125B may be provided in the second opening OP2 through a process such as electroplating. Thereafter, the lower redistribution layer 150 may be formed through a redistribution process. The process of the lower redistribution layer 150 is similar to the process of the upper redistribution layer 140.

Referring to FIG. 6J, a lateral portion of the second insulating layer 131 may be removed. The frame FR1 that was located on a side of the glass core substrate 110 during the manufacturing process may be removed by cutting the portion of the second insulating layer 131 indicated by the dashed lines and the arrow. Thereafter, the external connection terminal 155 and the passive device 156 may be arranged on each of the plurality of external connection pads 154. The order of the process of cutting the second insulating layer 131 and the process of arranging the external connection terminal 155 and the passive device 156 may be different from the above.

Referring to FIG. 6K, the first semiconductor device 210 and the second semiconductor device 310 may be arranged on the upper redistribution layer 140. The first chip pad 211 of the first semiconductor device 210 may be connected through the upper connection pad 144 and the first chip connection member 212. Thereafter, the underfill material layer 230 may be arranged between the first semiconductor device 210 and the upper surface of the upper redistribution layer 140 by, for example, a capillary underfill method. The case of the second semiconductor device 310 is also similar to the first semiconductor device 210. Through these processes, the semiconductor package 2 according to embodiments may be manufactured.

While the embodiments have been particularly illustrated and described with reference to the accompanying drawings, it will be understood by those of skill in the art that various changes in form and details may be made therein without departing from the spirit and scope of the inventive concept. Therefore, it should be understood that the above-described embodiments are exemplary in all respects and do not limit the scope of the inventive concept.

While the inventive concept has been particularly shown and described with reference to embodiments thereof, it will be understood that various changes in form and details may be made therein without departing from the scope of the following claims.

What is claimed is:

1. A semiconductor package comprising:
a glass core interposer comprising a glass core substrate, a plurality of through electrodes penetrating the glass core substrate, a first insulating layer at least partially covering each of an upper surface and a lower surface of the glass core substrate that is opposite an upper surface thereof, a second insulating layer at least partially surrounding the first insulating layer and the glass core substrate, and an upper redistribution layer on an upper surface of the second insulating layer; and
a first semiconductor device on an upper surface of the glass core interposer,
wherein the first insulating layer is free of filler, and
the second insulating layer comprises filler.

2. The semiconductor package of claim 1, further comprising upper core vias connected to upper ends of the plurality of through electrodes, and lower core vias connected to lower ends of the plurality of through electrodes,
wherein the first insulating layer comprises a first upper-surface insulating layer at least partially covering the upper surface of the glass core substrate, and a first lower-surface insulating layer at least partially covering the lower surface of the glass core substrate,
the second insulating layer comprises a second upper-surface insulating layer at least partially covering the first upper-surface insulating layer, and a second lower-surface insulating layer at least partially covering the first lower-surface insulating layer, and
an outer edge of the first upper-surface insulating layer and an outer edge of the first lower-surface insulating layer are coplanar with an outer edge of the glass core substrate.

3. The semiconductor package of claim 2, wherein the second insulating layer at least partially surrounds a side surface of the glass core substrate and at least partially surrounds side surfaces of the first upper-surface insulating layer and the first lower-surface insulating layer, and
a side surface of the second insulating layer is laterally spaced apart from the side surface of the glass core substrate.

4. The semiconductor package of claim 2, wherein a planar area of the second insulating layer is larger than respective planar areas of the first upper-surface insulating layer and the first lower-surface insulating layer.

5. The semiconductor package of claim 3, wherein a distance between the side surface of the second insulating layer and the side surface of the glass core substrate is about 30 μm to about 500 μm.

6. The semiconductor package of claim 2, wherein the first insulating layer comprises at least one of a photosensitive polyimide, polybenzoxazole, a phenol-based polymer, benzocyclobutene, lead oxide (PbO), polyhydroxystyrene (PHS), a silicon oxide film, a silicon nitride film, or a silicon oxynitride film, and
the second insulating layer comprises at least one of Ajinomoto Build-up Film (ABF) or prepreg.

7. The semiconductor package of claim 2, wherein the upper core vias at least partially penetrate the first upper-surface insulating layer and the second upper-surface insulating layer, and
the lower core vias at least partially penetrate the second upper-surface insulating layer and the second lower-surface insulating layer.

8. The semiconductor package of claim 7, wherein respective levels away from the glass core substrate of one surface of the first upper-surface insulating layer, one end of the through electrode, and one surface of the upper core vias are identical to each other, and
respective levels away from the glass core substrate of one surface of the first lower-surface insulating layer, one end of the through electrode, and one surface of the lower core vias are identical to each other.

9. The semiconductor package of claim 1, wherein the glass core interposer further comprises a lower redistribution layer on a lower surface of the second insulating layer,
the upper redistribution layer comprises an upper redistribution pattern and an upper redistribution insulating layer,
the upper redistribution pattern comprises an upper redistribution line pattern and an upper redistribution via pattern,
the upper redistribution via pattern has a horizontal width that increases with distance away from the glass core substrate,
the lower redistribution layer comprises a lower redistribution pattern and a lower redistribution insulating layer,
the lower redistribution pattern comprises a lower redistribution line pattern and a lower redistribution via pattern, and
the lower redistribution via pattern has a horizontal width that increases with distance away from the glass core substrate.

10. The semiconductor package of claim 1, further comprising:
a concave portion that is recessed into the glass core substrate with respect to the upper surface of the glass core substrate;
a bridge chip in the concave portion; and
a second semiconductor chip on the glass core interposer and laterally spaced apart from the first semiconductor device.

11. The semiconductor package of claim 10, further comprising upper core vias connected to upper ends of the plurality of through electrodes, and lower core vias connected to lower ends of the plurality of through electrodes,
wherein the first insulating layer comprises a first upper-surface insulating layer at least partially covering the upper surface of the glass core substrate, and a first lower-surface insulating layer at least partially covering the lower surface of the glass core substrate,
the second insulating layer comprises a second upper-surface insulating layer at least partially covering the first upper-surface insulating layer, and a second lower-surface insulating layer at least partially covering the first lower-surface insulating layer,
the upper core vias at least partially penetrate the first upper-surface insulating layer and the second upper-surface insulating layer, and
the lower core vias at least partially penetrate the second upper-surface insulating layer and the second lower-surface insulating layer.

12. The semiconductor package of claim 11, wherein the first upper-surface insulating layer is between the bridge chip and the glass core substrate.

13. A semiconductor package comprising:
a glass core interposer comprising a glass core substrate, a plurality of through electrodes penetrating the glass core substrate, a first insulating layer at least partially covering each of an upper surface and a lower surface of the glass core substrate that is opposite the upper surface thereof, a second insulating layer at least partially surrounding the first insulating layer and the glass core substrate, an upper redistribution layer on an upper surface of the second insulating layer, upper core vias connected to upper ends of the plurality of through electrodes, and lower core vias connected to lower ends of the plurality of through electrodes; and
a first semiconductor device on an upper surface of the glass core interposer,
wherein the first insulating layer comprises a first upper-surface insulating layer at least partially covering the upper surface of the glass core substrate, and a first lower-surface insulating layer at least partially covering the lower surface of the glass core substrate,
the upper core vias at least partially penetrate the first upper-surface insulating layer,
the lower core vias at least partially penetrate the first lower-surface insulating layer, and
the upper core vias and the lower core vias are not in contact with the second insulating layer.

14. The semiconductor package of claim 13, wherein the first insulating layer comprises a non-photoimageable dielectric material,
the first insulating layer is free of filler, and
the second insulating layer comprises filler.

15. The semiconductor package of claim 14, wherein the first insulating layer comprises at least one of a silicon oxide film, a silicon nitride film, or a silicon oxynitride film, and
the second insulating layer comprises at least one of Ajinomoto Build-up Film (ABF) or prepreg.

16. The semiconductor package of claim 14, wherein the second insulating layer at least partially surrounds a side surface of the glass core substrate and at least partially surrounds side surfaces of the first upper-surface insulating layer and the first lower-surface insulating layer, and
a side surface of the second insulating layer is laterally spaced apart from the side surface of the glass core substrate.

17. The semiconductor package of claim 13, further comprising:
a concave portion that is recessed into the glass core substrate with respect to the upper surface of the glass core substrate;
a bridge chip in the concave portion; and
a second semiconductor chip on the glass core interposer and laterally spaced apart from the first semiconductor device,
wherein the first upper-surface insulating layer is between the bridge chip and the glass core substrate.

18. The semiconductor package of claim 13, further comprising a lower redistribution layer on a lower surface of the second insulating layer,
wherein the upper redistribution layer comprises an upper redistribution pattern and an upper redistribution insulating layer,
the upper redistribution pattern comprises an upper redistribution line pattern and an upper redistribution via pattern,
the upper redistribution via pattern has a horizontal width that increases with distance away from the glass core substrate,
the lower redistribution layer comprises a lower redistribution pattern and a lower redistribution insulating layer,
the lower redistribution pattern comprises a lower redistribution line pattern and a lower redistribution via pattern, and
the lower redistribution via pattern has a horizontal width that increases with distance away from the glass core substrate.

19. A semiconductor package comprising:
a glass core interposer comprising a glass core substrate, a plurality of through electrodes penetrating the glass core substrate, a first insulating layer at least partially covering each of an upper surface and a lower surface of the glass core substrate that is opposite the upper surface thereof, a second insulating layer at least partially surrounding the first insulating layer and the glass core substrate, an upper redistribution layer on an upper surface of the second insulating layer, and a lower redistribution layer on a lower surface of the second insulating layer that is opposite the upper surface thereof;
a first semiconductor device on an upper surface of the glass core interposer;
upper core vias connected to upper ends of the plurality of through electrodes; and
lower core vias connected to lower ends of the plurality of through electrodes,
wherein the first insulating layer comprises a first upper-surface insulating layer at least partially covering the upper surface of the glass core substrate, and a first lower-surface insulating layer at least partially covering the lower surface of the glass core substrate,
the second insulating layer comprises a second upper-surface insulating layer at least partially covering the first upper-surface insulating layer, and a second lower-surface insulating layer at least partially covering the first lower-surface insulating layer,
an outer edge of the first upper-surface insulating layer and an outer edge of the first lower-surface insulating layer are coplanar with an outer edge of the glass core substrate,
the second insulating layer at least partially surrounds a side surface of the glass core substrate and at least partially surrounds side surfaces of the first upper-surface insulating layer and the first lower-surface insulating layer,
a side surface of the second insulating layer is laterally spaced apart from the side surface of the glass core substrate,
a planar area of the second insulating layer is larger than planar areas of the first upper-surface insulating layer and the first lower-surface insulating layer,
the first insulating layer is free of filler,
the second insulating layer comprises filler,
the upper core vias at least partially penetrate the first upper-surface insulating layer and the second upper-surface insulating layer,
the lower core vias at least partially penetrate the second upper-surface insulating layer and the second lower-surface insulating layer,
respective levels away from the glass core substrate of one surface of the first upper-surface insulating layer, one end of the through electrode, and one surface of the upper core vias are identical to each other,
respective levels away from the glass core substrate of one surface of the first lower-surface insulating layer, one end of the through electrode, and one surface of the lower core vias are identical to each other,
the upper redistribution layer comprises an upper redistribution pattern and an upper redistribution insulating layer,
the upper redistribution pattern comprises an upper redistribution line pattern and an upper redistribution via pattern,
the upper redistribution via pattern has a horizontal width that increases with distance away from the glass core substrate,
the lower redistribution layer comprises a lower redistribution pattern and a lower redistribution insulating layer,
the lower redistribution pattern comprises a lower redistribution line pattern and a lower redistribution via pattern, and
the lower redistribution via pattern has a horizontal width that increases with distance away from the glass core substrate.

20. The semiconductor package of claim 19, wherein the first insulating layer comprises at least one of a photosensitive polyimide, polybenzoxazole, a phenol-based polymer, benzocyclobutene, lead oxide (PbO), polyhydroxystyrene (PHS), a silicon oxide film, a silicon nitride film, or a silicon oxynitride film,
the second insulating layer comprises at least one of Ajinomoto Build-up Film (ABF) or prepreg, and
a distance between the side surface of the second insulating layer and the side surface of the glass core substrate is about 30 μm to about 500 μm.
